(19) United States
(12) Patent Application Publication
(10) Pub. No.: US 2007/0107932 A1
(43) Pub. Date: May 17, 2007

(54) Moisture resistant chip package

(76) Inventors: Linas A. Jauniskis, West Newton, MA (US); Brian Farrell, Quincy, MA (US)

Correspondence Address: IANDIORIO & TESKA;INTELLECTUAL PROPERTY LAW ATTORNEYS, 260 BEAR HILL ROAD, WALTHAM, MA, 02451-1018, US

(21) Appl. No.: 11/588,718

(22) Filed: Oct. 27, 2006

Related U.S. Application Data
(60) Provisional application No. 60/735,070, filed on Nov. 9, 2005.

(51) Int. Cl. H05K 1/16

(52) U.S. Cl. 174/260

(57) ABSTRACT

A moisture resistant chip package includes a substrate, a chip mounted to the substrate, and a cover over the chip and secured to the substrate. The substrate and/or the cover includes at least one LCP layer. Each moisture ingress path through the thickness of any LCP layer is restricted by an impermeable blocking structure to impede moisture ingress through the thickness of any LCP layer.

### RELATED APPLICATIONS

This application claims benefit of U.S. Provisional Application No. 60/735,070, filed Nov. 9, 2005, entitled “3D CHIP SCALE (CSP) OR NEAR CSP PACKAGING”.

### FIELD OF THE INVENTION

This subject invention relates to chip packages and chip packaging techniques.

### BACKGROUND OF THE INVENTION

Those skilled in the art have proposed the use of liquid crystal polymer (LCP) material in chip packaging approaches. See, for example, U.S. Pat. Nos. 6,320,257 and 6,977,187 incorporated herein by this reference. It was thought that the LCP material provided adequate moisture protection while at the same time the LCP material acted as a good electrical substrate. Advantageously, LCP material can be processed using standard printed circuit board and/or wafer fabrication techniques. Other advantages associated with LCP materials are known to those skilled in the art.

Unfortunately, the moisture impermeability of LCP is not always sufficient for some applications. The moisture impermeability of LCP materials is far better than most standard printed circuit board materials but it is not as good as glass, for example, or metal. Thus, the use of LCP materials in chip packages has not met its full potential especially when moisture ingress to the interior of the package and the chip is a concern.

### SUMMARY OF THE INVENTION

It is therefore an object of this invention to provide a moisture resistant chip package which still allows the use of LCP materials.

It is a further object of this invention to provide such a moisture resistant chip package which can vary in configuration to meet the needs of the designer.

It is a further object of this invention to provide a new method of packaging a chip to render it highly impervious to moisture using organic (LCP) packaging materials.

The subject invention results from the realization that a moisture resistant chip package advantageously incorporating LCP material either in the chip substrate and/or in the cover for the chip is effected by studying each moisture ingress path associated with the package and blocking each moisture ingress path through the thickness of any LCP layer with a blocking layer or structure so moisture is then constrained to traverse laterally through any LCP material. Since the moisture ingress path through the LCP material is forced to have a lateral component, the amount of time it takes the moisture to traverse the LCP material is much longer than for moisture allowed to traverse directly through the thickness of the LCP material.

The subject invention, however, in other embodiments, need not achieve all these objectives and the claims hereof should not be limited to structures or methods capable of achieving these objectives.

The subject invention relates to a moisture resistant chip package. There is a substrate, a chip mounted to the substrate, and a cover over the chip and secured to the substrate. The substrate and/or the cover includes at least one LCP layer. But, each moisture ingress path through the thickness of any LCP layer blocked by an impermeable blocking structure to impede moisture ingress through the thickness of any LCP layer.

In one example, the substrate includes an impermeable blocking layer such as a copper foil backplane layer adjacent an LCP layer. Typically, the substrate will also include a conductive routing layer for electrically connecting the chip to contacts on the substrate outside of the cover. The substrate may include at least two conductive routing layers having traces offset from each other to form an impermeable blocking structure. In another example, the conductive routing layers are configured to electrically connect the chip to ball grid contacts on the back side of the chip.

One substrate may include a first LCP layer with leads thereon for the chip, vias through the first LCP layer for electrically connecting the leads to traces of a conductive routing layer adjacent the first LCP layer, a second LCP layer adjacent the conductive routing layer, and an impermeable blocking layer adjacent the second LCP layer. In one example, there is a solder ring about the chip on the first LCP layer and a hermetic cover on the ring to constrain moisture ingress through the first LCP layer to have a lateral component around the solder ring. There may be contacts on the first LCP layer outside of the cover and vias through the first LCP layer electrically connecting the contacts with the traces of the conductive routing layer.

In another example, the substrate includes a first LCP layer with leads thereon for the chip, vias through the first LCP layer for electrically connecting the leads to the traces of a first conductive routing layer adjacent the first LCP layer, and a second LCP layer adjacent the first conductive routing layer with vias therethrough for electrically connecting the traces of the first conductive routing layer to traces of a second conductive routing layer adjacent the second LCP layer. The traces of the first conductive routing layer are configured to be offset from the traces of the second conductive layer.

In one example, the substrate includes an LCP layer with contacts thereon and LCP material on the contacts. The cover then includes LCP material joined with the LCP material on the contacts on the LCP layer of the substrate. Conversely, the substrate may include an LCP layer with contacts thereon, LCP material on the contacts, and metallization on the LCP material. The cover then includes metallization joined with the metallization on the LCP material on the contacts of the substrate.

The cover may include an optical header. Or, the cover may include an LCP layer with a chip mounted thereto.

In another possible design, the substrate includes an LCP layer with solder ball contacts thereon and the cover includes a semiconductor ball grid array chip with ball grid array interconnects mated with the solder ball contacts of the substrate.

In still another possible design, the substrate includes an LCP layer and silicon based integrated circuitry laminated to the LCP layer. There may be interleaved stacks of substrates and silicon based integrated circuitry.

One moisture resistant chip package in accordance with this invention features a substrate, a chip mounted to the substrate, and a cover over the chip and secured to the substrate. The substrate includes at least one LCP layer and an impermeable blocking layer adjacent the LCP layer to impede moisture ingress through the thickness of the LCP layer.

One moisture resistant chip package in accordance with this invention features a substrate, a chip mounted to the substrate, and a cover over the chip and secured to the substrate. The substrate includes at least one LCP layer and an impermeable blocking structure adjacent the LCP layer to impede moisture ingress through the thickness of the LCP layer.

The subject invention also includes a method of packaging a chip. A substrate is chosen for a chip and includes one or more LCP layers. Electrical routing for the chip is provided in the substrate. Any moisture ingress paths through the thickness of any LCP layer of the substrate are analyzed. Then, a blocking structure is added to the substrate to constrain moisture ingress through any LCP layer of the substrate to have a lateral component.

The substrate may be chosen to include an impermeable blocking layer adjacent to an LCP layer. In such a design, a conductive routing layer may include traces for electrically connecting the chip to contacts on the substrate outside of the cover.

Or, the electrical routing may include adding conductive routing layers to the substrate designed to have traces offset from each other to form an impermeable blocking structure. The conductive routing layers may be configured to electrically connected the chip to ball grid contacts on a back side of the package.

In one example, the substrate is chosen to include a first LCP layer with leads thereon for the chip, vias are formed through the first LCP layer for electrically connecting the leads to traces of a conductive routing layer adjacent the first LCP layer, a second LCP layer is chosen to be adjacent the conductive routing layer, and an impermeable blocking layer is formed adjacent the second LCP layer. Typically, a ring is formed about the chip on the first LCP layer and a metal cover is secured to the ring to constrain moisture ingress through the first LCP layer to have a lateral component. Contacts on the first LCP layer may be added outside of the cover and vias formed through the first LCP layer electrically connecting the contacts with the traces of the conductive routing layer.

In another example, the substrate is chosen to include a first LCP layer with leads thereon for the chip, vias are formed through the first LCP layer for electrically connecting the leads to the traces of a first conductive routing layer adjacent the first LCP layer, a second LCP layer is added adjacent the first conductive routing layer with vias therethrough for electrically connecting the traces of the first conductive routing layer to traces of a second conductive routing layer adjacent the second LCP layer, and the traces of a first conductive routing layer are designed to be offset from the traces of the second conductive routing layer.

The method may further include different ways of choosing a joining process between a cover and the substrate. In one example, the joining process includes adding LCP material to the substrate and adding LCP material to the cover and joining the LCP materials. In another example, metallization is added to the cover and metallization is added to the substrate and the metallization of the cover is joined with the metallization of the substrate.

A cover can be selected to include an optical header. In another example, the substrate includes solder ball contacts formed thereon for a semi-conductor ball grid array chip with ball grid array interconnects to be mated with the solder ball contacts for the substrate. In still another example, silicon based integrated circuitry is directly laminated to an LCP layer of the substrate. In addition, stacks of substrates and silicon based integrated circuitry can be interleaved in a three-dimensional stacked structure.

### BRIEF DESCRIPTION OF THE SEVERAL VIEWS OF THE DRAWINGS

Other objects, features and advantages will occur to those skilled in the art from the following description of a preferred embodiment and the accompanying drawings, in which:

FIG. 1 is a highly schematic cross-sectional view showing a prior art LCP based substrate for a chip package;

FIG. 2 is a highly schematic cross-sectional view showing one example of a package including an LCP substrate in accordance with the subject invention wherein moisture is constrained to traverse laterally through the LCP layer of the substrate resulting in a perimeter lead type package;

FIG. 3 is a highly schematic cross-sectional view of another example of a moisture resistant chip package in accordance with the subject invention showing another way moisture can be constrained to traverse laterally through the LCP material of the chip package substrate resulting in a ball grid array type package;

FIG. 4 is a highly schematic cross-sectional view showing how a package cover in accordance with the subject invention can include an optical header;

FIG. 5 is a highly schematic cross-sectional view showing how a chip package cover in accordance with the subject invention can include a second chip;

FIG. 6 is a highly schematic cross-sectional view showing another example of a moisture resistant chip package in accordance with the subject invention;

FIG. 7 is a highly schematic cross-sectional view showing still another example of a moisture resistant chip package in accordance with the subject invention where a semi-conductor ball grid array chip is mated to a substrate with an LCP layer;

FIGS. 8A-8E are highly schematic cross-sectional views showing how integrated circuitry in a semiconductor wafer can be directly laminated to a substrate including an LCP layer in accordance with the subject invention; and

FIGS. 9A-9C are schematic cross-sectional views showing how a number of three-dimensional chip scale laminated structures can be fabricated in accordance with the subject invention.

### DETAILED DESCRIPTION OF THE INVENTION

Aside from the preferred embodiment or embodiments disclosed below, this invention is capable of other embodiments and of being practiced or being carried out in various ways. Thus, it is to be understood that the invention is not limited in its application to the details of construction and the arrangements of components set forth in the following description or illustrated in the drawings. If only one embodiment is described herein, the claims hereof are not to be limited to that embodiment. Moreover, the claims hereof are not to be read restrictively unless there is clear and convincing evidence manifesting a certain exclusion, restriction, or disclaimer.

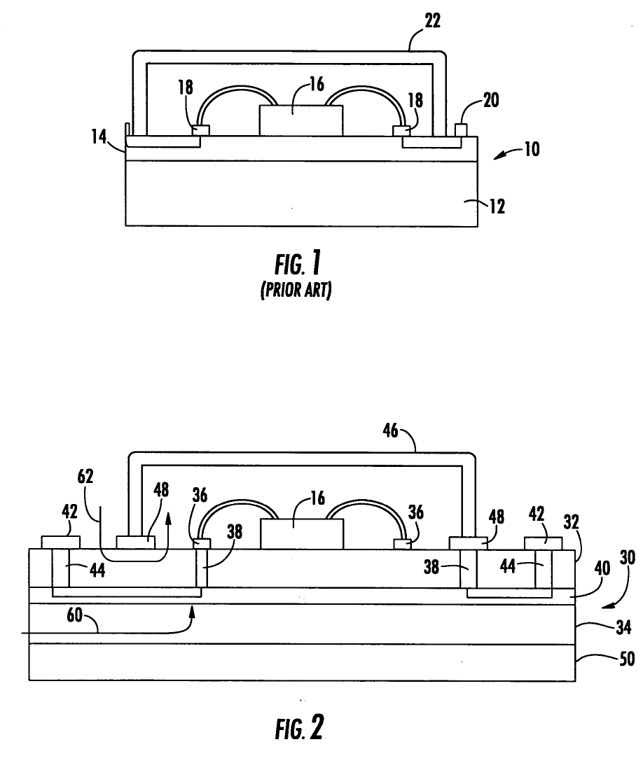

FIG. 1 schematically shows an example of prior art LCP substrate 10 with LCP layer 12 and conductive routing (e.g., copper) layer 14. Chip 16 is bonded to conductive routing layer 14 and wire bonded to leads 18 thereof. Electrical signals can be routed to perimeter leads 20 or through the thickness of LCP layer 12 to solder balls (not shown) on the back side of LCP layer 12 through plated vias therethrough. Cover 22 protects chip 16 and can be metal or may also be made of LCP.

LCP layer 12 provides a certain degree of moisture ingress protection to the interior of the package. LCP material is not sufficiently moisture resistant in some high reliability applications where moisture ingress must be severely limited to, for example, below <5000 ppm after accelerated aging, 1000 hrs at 85° C./85% RH. Testing, for example, proved that moisture permeated through the thickness of LCP layer 12 and then through the voids in metal routing layer 14 to the inside of the package potentially adversely affecting chip 16. And, when cover or lid 22 was made of LCP material, moisture permeated through the thickness of LCP cover 22 as well.

In the subject invention, in contrast, LCP material is advantageously used in the chip package with each moisture ingress path through the thickness of any LCP layer is noted and restricted in some fashion to lateral ingress. The result is a package which exceeds 5000 ppm after accelerated aging for 1000 hours at 85° C./85% RH.

For example, as shown in FIG. 2, substrate 30 may include LCP layers 32 and 34. LCP layer 32 includes thereon chip 16 and leads 36 for wire bonds connected to chip 16. LCP layer 32 also includes plated conducted vias 38 therethrough connecting leads 36 with the traces of conductive routing layer 40 which then connect to perimeter leads 42 by plated vias 44 through the thickness of LCP layer 32. LCP layer 34 is also provided behind routing layer 40 and/or the traces of routing layer 40 (e.g., copper foil) are patterned on LCP layer 34. Cover 46 may be metal and secured to LCP layer 32 by solder ring 48. Cover 46 may also be plated plastic or ceramic, for example.

In this particular design, the moisture ingress paths through the thickness of substrate 30 are noted. That is, there may be moisture ingress paths through the thickness of LCP layer 34, through the voids in conductive routing layer 40, and through the thickness of LCP layer 32 to the inside of package 30. Those moisture ingress paths are restricted in this invention by impervious blocking layer 50 (e.g., metallization such as copper foil). The result is that the only moisture ingress path through any LCP layer is constrained to have a lateral component as shown at 60 and 62 within LCP layers 34 and 32. The extent of the lateral moisture ingress path is designed by the appropriate choice of the width of solder ring 48 (for ingress path 62) to render package 30 sufficiently moisture resistant to pass the appropriate moisture permeability test to which the package is subject to. Tests have proven, for example, that the design of FIG. 2 resulted in a much better moisture impermeability than the design of FIG. 1 due to impermeable blocking layer 50 which may serve as a ground plane, for example, or as a heat spreader for thermal management.

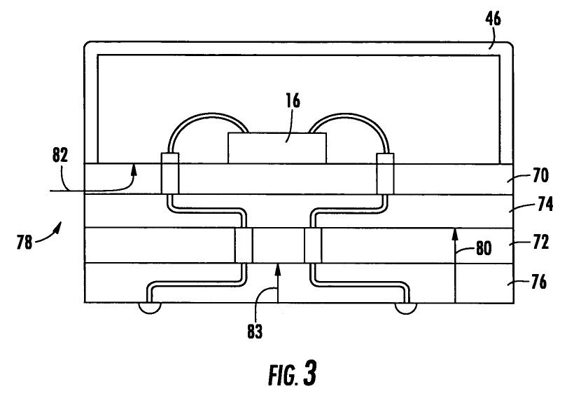

Or, in the case where a ball grid array type package is desired, LCP layers 70 and 72, FIG. 3 can be used each with plated through hole vias as shown offset from each other. Electrical routing layers 74 and 76 also are configured to have offset electrical traces as shown so that any moisture ingress path through the thickness of substrate 78 is blocked, for example, by the combination of routing layers 74 and 76. Moisture ingress path 80, for example, is blocked by metallization in layer 74. Moisture ingress path 82, as another example, is constrained to have a lateral component through LCP layer 70. Moisture ingress path 83, for example, is blocked by metallization in layer 72, e.g., a ground plane with clearance only around the vias in LCP layer 72.

The result can be a highly compact package leading to near chip scale or chip scale packaging. Exploiting the laminated printed circuit board architecture can lead to three-dimensional stacking and functional impermeability due to the small cross-section for moisture ingress through any LCP layer. These features lead to economical, scalable, and manufacturable solutions to various principal packaging problems such as reducing packaging size, maintaining performance, managing co-efficient of thermal extension miss-match, and hermeticity in organic packaging. A functionally hermetic package (defined as passing 1,000 hours using the 85/85 test) may include a semi-conductor chip laminated to an LCP printed circuit board substrate with only moisture ingress paths laterally through the printed circuit board.

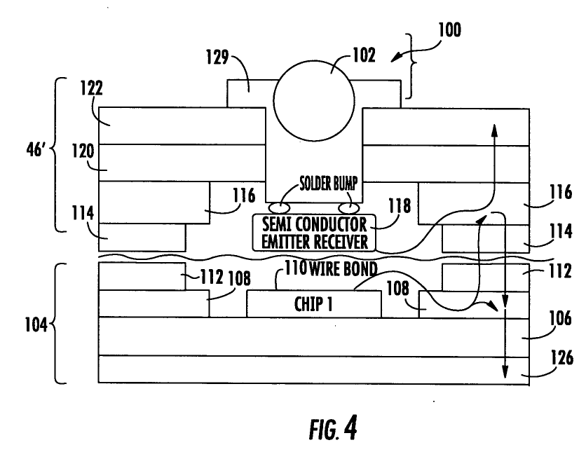

In another example, cover 46′, FIG. 4 includes optical header 100 including, for example, ball lens 102. Substrate 104 may take the form as shown in FIGS. 2 or 3 and may include LCP layer 106 with wire bond contacts 108 thereon for chip 110. LCP material 112 is disposed on contacts 108. Cover 46′ in this example includes LCP material 114 which mates with LCP material 112. LCP material 114 is on wire bond contacts 116 for opto-electronic semiconductor emitter/receiver chip 118. LCP layer 120, metallization layer 122, and ball lens shell 124 complete cover 46′. Electrical routing for chip 118 and chip 110 includes possible vias through LCP material layers 112, 114, 106, and 120 and routing layers with the appropriate leads structure in layers 122 and 126 and perhaps additional such layers or insulated traces on header 129 when the header is insulating and hermetic (glass or other oxide). Moisture blocking may be provided via the method discussed above with reference to FIGS. 2 and/or 3.

Package 160, FIG. 5 includes cover 46″ where LCP material 162 thereof also joins to LCP material 164 of substrate 166. Now, cover 46″ includes chip 168 wire bonded to contacts 170 on LCP layer 172. Substrate 166 also includes chip 174 wire bonded to contacts 176 on LCP layer 178. Electrical routing for chip 168 may includes vias through LCP layers 170 and 172 to the leads conductive routing layer 180 and/or through vias in LCP material layers 162 and 164 to contacts 176, through vias in LCP layer 178, and to the leads of conductive routing layer 182. Electrical routing for chip 174 may include vias through LCP layers 164 and 162 to contacts 170 and through vias in LCP layer 172 to the traces of conductive routing layer 180. Moisture blocking may be provided via the method discussed with reference to FIGS. 2 and/or 3 above.

Package 200, FIG. 6, in contrast, includes cover 46′″ where metallization 210 (e.g., copper) on LCP layer 212 joins via solder or an adhesive to metallization 214 (also copper) on LCP material 216 on contacts 218 for chip 220 on LCP layer 222 of substrate 224. Conductive layers 224 and 226 may include leads for electrical routing to the exterior of package 200. Note that moisture ingress through LCP layers 212, 216, and 222 is constrained to include a lateral component.

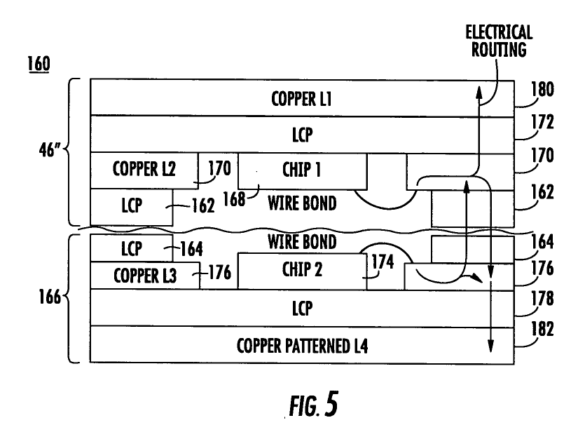

Package 250, FIG. 7, in another design, includes LCP layer 252 with solder ball contacts 254 thereon. In this example, “cover” 256 is a semiconductor ball grid array chip 258 with ball grid array interconnects mated via solder balls with solder ball contacts 254 of the substrate. Vias may be provided through LCP layer 252 and interconnect layer or layers 260 configured to block moisture ingress through the thickness of LCP layer 252 as discussed above with reference to FIG. 3.

In still another design, silicon based integrated circuitry is laminated directly to an LCP substrate. As shown in the example of FIGS. 7A-7E, silicon wafer 300, FIG. 7A includes etch stop 302, silicon functional layers 304, metallization 306, and silicon oxide adhesion layer 308. Substrate 310 includes LCP layer 312, copper redistribution layer 314, and LCP layer 316. In FIG. 7B, silicon oxide adhesion layer 308 is bonded (laminated) to LCP layer 312. Wafer 300, FIG. 7C, is mechanically thinned and then chemically etched, FIG. 7D. The etch stop layer is removed, FIG. 7E, resulting in moisture impervious silicon based integrated circuitry structures 320 on LCP substrate 322 which may include a ground metallization blocking layer as discussed above with reference to FIG. 2 or 3 or one or more properly configured re-distribution layers with the leads thereof offset to provide a blocking structure to prevent moisture ingress through the thickness of LCP layers 312, 316, and the like.

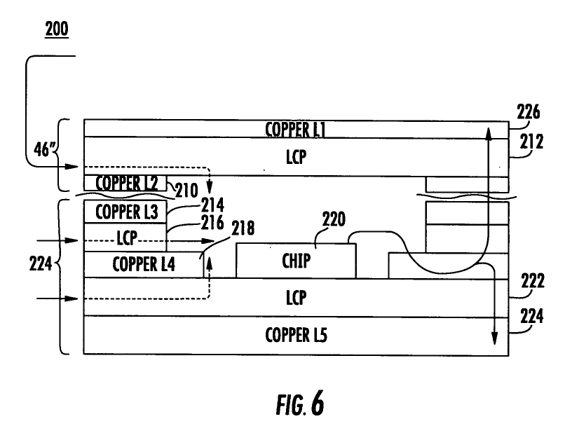

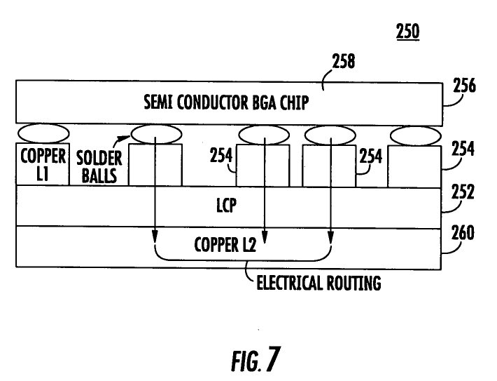

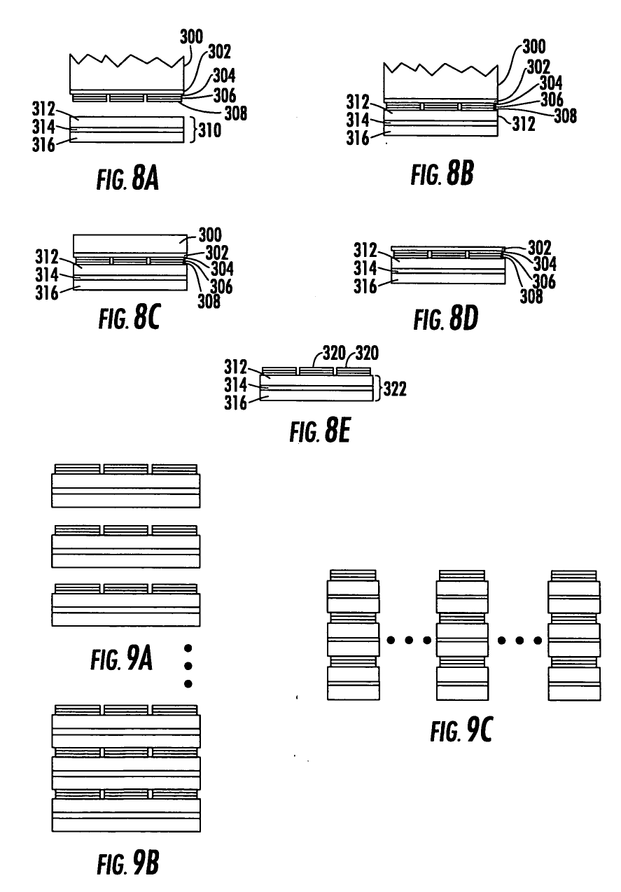

A number of these structures, as shown in FIGS. 8A-8C, can be aligned, and laminated together and then singulated resulting in epitaxial scale chip thickness package in a three-dimensional chip scale or near chip scale laminated packaging structure.

Accordingly, once the moisture ingress paths through the thickness of any LCP layer are analyzed, there are numerous ways to add blocking layers or structures which constrain moisture ingress through any LCP layer to have a lateral component enabling the package design to pass a 1,000 hour, 85/85 test. The result is a moisture resistant chip package which can vary in design and yet still allows the use of LCP materials where moisture permeability is a concern together with other desirable features of LCP organic packaging.

Although specific features of the invention are shown in some drawings and not in others, this is for convenience only as each feature may be combined with any or all of the other features in accordance with the invention. The words “including”, “comprising”, “having”, and “with” as used herein are to be interpreted broadly and comprehensively and are not limited to any physical interconnection. Moreover, any embodiments disclosed in the subject application are not to be taken as the only possible embodiments. Other embodiments will occur to those skilled in the art and are within the following claims.

In addition, any amendment presented during the prosecution of the patent application for this patent is not a disclaimer of any claim element presented in the application as filed: those skilled in the art cannot reasonably be expected to draft a claim that would literally encompass all possible equivalents, many equivalents will be unforeseeable at the time of the amendment and are beyond a fair interpretation of what is to be surrendered (if anything), the rationale underlying the amendment may bear no more than a tangential relation to many equivalents, and/or there are many other reasons the applicant can not be expected to describe certain insubstantial substitutes for any claim element amended.

What is claimed is:

1. A moisture resistant chip package comprising:
a substrate;
a chip mounted to the substrate;
a cover over the chip and secured to the substrate;
the substrate and/or the cover including at least one LCP layer; and
each moisture ingress path through the thickness of any LCP layer blocked by an impermeable blocking structure to impede moisture ingress through the thickness of any LCP layer.

2. The package of claim 1 in which the substrate includes an impermeable blocking layer adjacent an LCP layer.

3. The package of claim 2 in which the substrate further includes a conductive routing layer for electrically connecting the chip to contacts on the substrate outside of the cover.

4. The package of claim 1 in which the substrate includes at least two conductive routing layers having traces offset from each other to form the impermeable blocking structure.

5. The package of claim 4 in which the conductive routing layers are configured to electrically connect the chip to ball grid contacts on a back side of the chip.

6. The package of claim 2 in which the substrate includes a first LCP layer with leads thereon for the chip, vias through the first LCP layer for electrically connecting the leads to traces of a conductive routing layer adjacent the first LCP layer, a second LCP layer adjacent the conductive routing layer, and an impermeable blocking layer adjacent the second LCP layer.

7. The package of claim 6 further including a ring about the chip on the first LCP layer and a cover on the ring to constrain moisture ingress through the first LCP layer to have a lateral component.

8. The package of claim 7 further including contacts on the first LCP layer outside of the cover and vias through the first LCP layer electrically connecting said contacts with the traces of the conductive routing layer.

9. The package of claim 4 in which the substrate includes a first LCP layer with leads thereon for the chip, vias through the first LCP layer for electrically connecting the leads to the traces of a first conductive routing layer adjacent the first LCP layer, a second LCP layer adjacent the first conductive routing layer with vias therethrough for electrically connecting the traces of the first conductive routing layer to traces of a second conductive routing layer adjacent the second LCP layer, the traces of the first conductive routing layer offset from the traces of the second conductive layer.

10. The package of claim 1 in which the substrate includes an LCP layer with contacts thereon, LCP material on the contacts, and the cover includes LCP material joined with the LCP material on the contacts on the LCP layer of the substrate.

11. The package of claim 1 in which the substrate includes an LCP layer with contacts thereon, LCP material on the contacts, metallization on the LCP material and the cover includes metallization joined with the metallization on the LCP material on the contacts of the substrate.

12. The package of claim 1 in which the cover includes an optical header.

13. The package of claim 1 in which the cover includes an LCP layer with a chip mounted thereto.

14. The package of claim 1 in which the substrate includes an LCP layer with solder ball contacts thereon and the cover includes a semiconductor ball grid array chip with ball grid array interconnects mated with the solder ball contacts of the substrate.

15. The package of claim 1 in which the substrate includes an LCP layer and silicon based integrated circuitry laminated to the LCP layer.

16. The package of claim 15 in which there are interleaved stacks of substrates and silicon based integrated circuitry.

17. A moisture resistant chip package comprising:
a substrate;
a chip mounted to the substrate;
a cover over the chip and secured to the substrate;
the substrate including at least one LCP layer; and
an impermeable blocking layer adjacent the LCP layer to impede moisture ingress through the thickness of the LCP layer.

18. A moisture resistant chip package comprising:
a substrate;
a chip mounted to the substrate;
a cover over the chip and secured to the substrate;
the substrate including at least one LCP layer; and
an impermeable blocking structure adjacent the LCP layer to impede moisture ingress through the thickness of the LCP layer.

19. A method of packaging a chip, the method comprising:
choosing a substrate for a chip including one or more LCP layers;
providing electrical routing for the chip in the substrate;
analyzing any moisture ingress paths through the thickness of any LCP layer of the substrate; and
adding a blocking structure to the substrate to constrain moisture ingress through any LCP layer of the substrate to have a lateral component.

20. The method of claim 19 in which the substrate is chosen to include an impermeable blocking layer adjacent an LCP layer.

21. The method of claim 20 in which providing electrical routing includes forming a conductive routing layer to include traces for electrically connecting the chip to contacts on the substrate outside of the cover.

22. The method of claim 19 in which providing electrical routing includes adding conductive routing layers designed to have traces offset from each other to form an impermeable blocking structure.

23. The method of claim 22 in which the conductive routing layers are configured to electrically connected the chip to ball grid contacts on a back side of the package.

24. The method of claim 19 in which the substrate is chosen to include a first LCP layer with leads thereon for the chip, vias are formed through the first LCP layer for electrically connecting the leads to traces of a conductive routing layer adjacent the first LCP layer, a second LCP layer is chosen to be adjacent the conductive routing layer, and an impermeable blocking layer is formed adjacent the second LCP layer.

25. The method of claim 24 further including forming a ring about the chip on the first LCP layer and securing a metal cover on the ring to constrain moisture ingress through the first LCP layer to have a lateral component.

26. The method of claim 25 further including adding contacts on the first LCP layer outside of the cover and forming vias through the first LCP layer electrically connecting the contacts with the traces of the conductive routing layer.

27. The method of claim 19 in which the substrate is chosen to include a first LCP layer with leads thereon for the chip, vias are formed through the first LCP layer for electrically connecting the leads to the traces of a first conductive routing layer adjacent the first LCP layer, a second LCP layer is added adjacent the first conductive routing layer with vias therethrough for electrically connecting the traces of the first conductive routing layer to traces of a second conductive routing layer adjacent the second LCP layer, and the traces of a first conductive routing layer are designed to be offset from the traces of the second conductive routing layer.

28. The method of claim 19 further including the step of choosing a joining process between a cover and the substrate.

29. The method of claim 28 in which choosing the joining process includes adding LCP material to the substrate and adding LCP material to the cover and joining the said LCP materials.

30. The method of claim 28 in which choosing a joining process includes adding metallization to the cover and metallization to the substrate and joining the metallization of the cover with the metallization of the substrate.

31. The method of claim 19 in which a cover is selected to include fabricating a cover to include an optical header.

32. The method of claim 19 in which choosing the substrate includes forming solder ball contacts thereon for a semi-conductor ball grid array chip with ball grid array interconnects to be mated with the solder ball contacts for the substrate.

33. The method of claim 19 in which silicon based integrated circuitry is directly laminated to an LCP layer of the substrate.

34. The method of claim 33 further including the step of interleaving stacks of substrates and silicon based integrated circuitry.
